(19) United States
(12) Patent Application Publication
(10) Pub. No.: US 2014/0291599 A1
(43) Pub. Date: Oct. 2, 2014

(54) RESISTIVE RANDOM ACCESS MEMORY

(71) Applicant: Intellectual Discovery Co., Ltd., Seoul (KR)

(72) Inventor: Hyun Sang Hwang, Pohang-si (KR)

(73) Assignee: INTELLECTUAL DISCOVERY CO., LTD., Seoul (KR)

(21) Appl. No.: 14/227,129

(22) Filed: Mar. 27, 2014

(30) Foreign Application Priority Data
Mar. 28, 2013 (KR) 10-2013-0033640

(51) Int. Cl. H01L 45/00

(52) U.S. Cl. CPC H01L 45/1293; H01L 45/08; H01L 45/1266
USPC 257/2

(57) ABSTRACT

Disclosed is a nonvolatile resistive random access memory. The nonvolatile resistive random access memory includes a first electrode, a second electrode, an ion conducting layer disposed between the first and second electrodes, a first heat diffusion preventing layer formed on the first electrode, and a second heat diffusion preventing layer formed on the second electrode. Since a temperature of a switching region of a device increases by adding the heat diffusion preventing layer, an operation speed increases by ten or more times, and a data retention of the device can be identically maintained. Accordingly, a voltage-time dilemma can be solved without an increase in an area of the device, thereby improving a degree of integration.

### CROSS-REFERENCE TO RELATED APPLICATIONS

This application claims priority under 35 U.S.C. §119 to Korean Patent Application No. 10-2013-0033640, filed on Mar. 28, 2013, the disclosure of which is incorporated herein by reference in its entirety.

### TECHNICAL FIELD

The present invention relates to a memory, and more particularly, to a nonvolatile resistive random access memory (ReRAM).

### BACKGROUND

Recently, researched is being done for next-generation nonvolatile memories that have lower power consumption and a higher degree of integration than flash memories. Examples of the next-generation nonvolatile memories include phase change RAMs (PRAMs) that use a state change of a phase change material such as an chalcogenide alloy, magnetic RAMs that use a resistance change of a magnetic tunnel junction (MTJ) thin film based on a magnetization state of a ferromagnetic material, ferroelectric RAMs that use a polarization of a ferroelectric material, and ReRAMs that use a resistance change of a variable resistance material.

In the memories, the ReRAMs include a resistance change memory cell that includes an upper electrode, and a lower electrode, and a variable resistance material formed therebetween. The ReRAMs have a characteristic in which a resistance of the variable resistance material is changed according to voltages respectively applied to the upper electrode and the lower electrode.

After the ReRAM is manufactured, by applying a very high level of filament formation voltage to the resistance change memory cell, a filament is formed in the variable resistance material.

The filament is a current path of a cell current that flows between the upper electrode and the lower electrode. After the filament is formed, the variable resistance material may be reset by applying a reset voltage, or the variable resistance material may be set up by applying a setup voltage.

The ReRAMs have a filament-type switching mechanism, and thus have a fast switching characteristic, a stable retention characteristic, etc. However, due to a randomly formed filament, it is difficult to fundamentally secure a stable switching characteristic.

Moreover, the ReRAMs should operate at a fast speed under a program voltage, and have ten-year data retention in a read mode. However, it is difficult to simultaneously satisfy the two conditions by using current technology.

To this end, technology has been developed in which two switches are connected in series, and a desired program speed and a desired data retention are secured by parallelly programming the two switches. In this case, however, a structure of a device becomes complicated, and an area of the device increases.

Moreover, technology for easily controlling a resistance switching characteristic of a GST-based phase change device by adding a separate heater terminal is disclosed in U.S. Pat. No. 8,183,551. Even in this case, however, an area of a device increases.

### SUMMARY

Accordingly, the present invention provides a ReRAM in which a heat diffusion preventing layer is formed on an upper and electrode and a lower electrode, and thus, a switching speed is considerably improved without an increase in an area of a device.

The present invention also provides a ReRAM in which an anti-diffusion layer for controlling a mobility of ions is additionally provided, thereby improving a retention characteristic of a device.

The object of the present invention is not limited to the aforesaid, but other objects not described herein will be clearly understood by those skilled in the art from descriptions below.

In one general aspect, a resistive random access memory (ReRAM) includes: a first electrode; a second electrode; an ion conducting layer disposed between the first and second electrodes; a first heat diffusion preventing layer formed on the first electrode; and a second heat diffusion preventing layer formed on the second electrode.

At least one of the first and second heat diffusion preventing layers may include Ge₂Sb₂Te₅.

The ReRAM may further include at least one or more insulation layers formed on the first or second electrode contacting the ion conducting layer, and configured to prevent ions from being conducted.

The at least one or more insulation layers may include Ti oxide or Si oxide.

In the at least one or more insulation layers, a first insulation layer including Ti oxide and a second insulation layer including Si oxide may be formed in a layered structure.

The at least one or more insulation layers may be formed in a multi-layer thin film structure having different degrees of ion diffusion.

The ion conducting layer may be formed of at least one of metal oxide, Pr_{0.7}Ca_{0.3}MnO₃ (PCMO), chalcogenide, perovskite, and a metal-doped solid electrolyte.

Other features and aspects will be apparent from the following detailed description, the drawings, and the claims.

### BRIEF DESCRIPTION OF THE DRAWINGS

FIG. 1 is a view illustrating a structure and operation characteristic of a general PMC device.

FIG. 2 is a view illustrating a cross-sectional surface of a memory according to an embodiment of the present invention.

FIG. 3 is a view illustrating a cross-sectional surface of a memory according to another embodiment of the present invention.

FIG. 4 is a diagram for describing an improved effect of the memory according to an embodiment of the present invention.

### DETAILED DESCRIPTION OF EMBODIMENTS

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. In the following description, the technical terms are used only for explaining a specific exemplary embodiment while not limiting the present invention. The terms of a singular form may include plural forms unless specifically mentioned.

Hereinafter, exemplary embodiments of the present invention will be described in detail with reference to the accompanying drawings. In adding reference numerals for elements in each figure, it should be noted that like reference numerals already used to denote like elements in other figures are used for elements wherever possible. Moreover, detailed descriptions related to well-known functions or configurations will be ruled out in order not to unnecessarily obscure subject matters of the present invention.

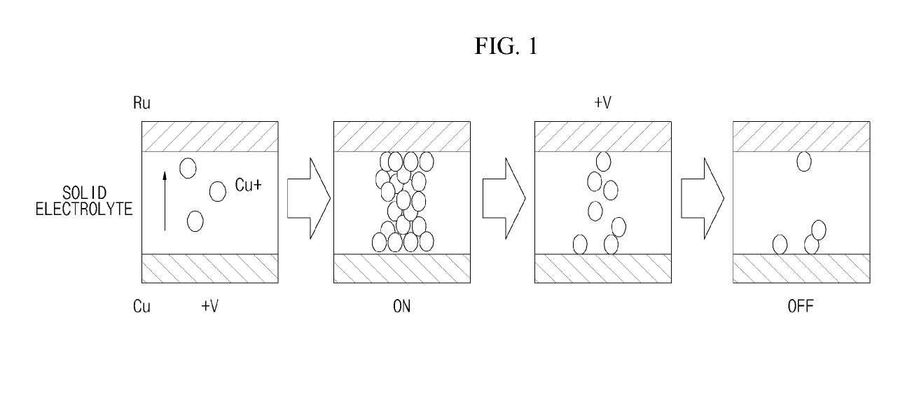

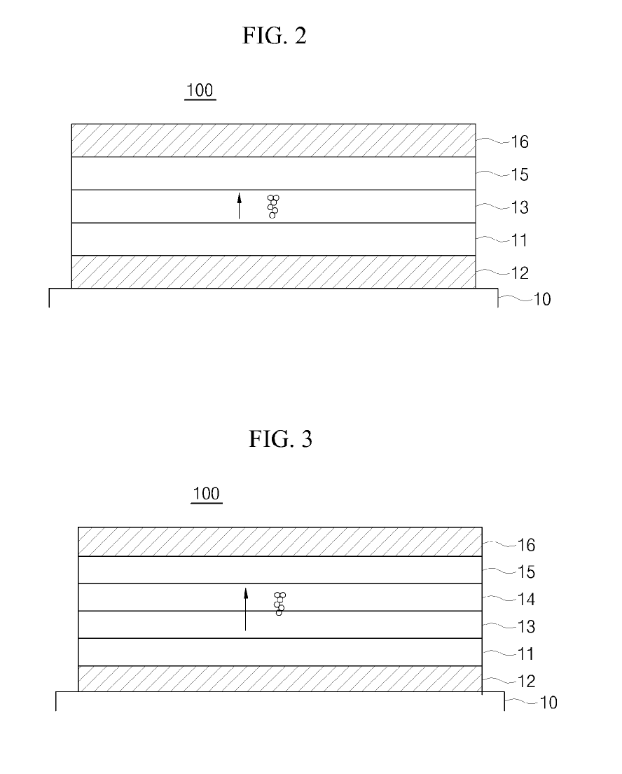

FIG. 1 is a view illustrating a structure and operation characteristic of a general PMC device. The characteristic of the general PMC device will be first described with reference to FIG. 1, and through comparison, a characteristic of a memory according to an embodiment of the present invention will be described with reference to FIGS. 2 to 4.

As illustrated in FIG. 1, the general PMC device includes a metal electrode formed of copper (Cu), a metal electrode formed of ruthenium (Ru), and an ion conducting layer formed therebetween.

The PMC device allows a current to flow into a nonconductive material and prevents the current from flowing to the nonconductive material by using an electrolyte characteristic of an amorphous chalcogenide material, thereby generating a signal of 0 and a signal of 1. In the PMC device, a part in which switching of a voltage is performed is formed by light-doping silver (Ag) or Cu on an amorphous chalcogenide combination, and Ag or Cu ions receiving energy generated by irradiated light penetrate into a chalcogenide thin film, and are located at defects of the chalcogenide thin film.

The Ag or Cu ions uniformly distributed on the chalcogenide thin film are changed to superionic conductors, thereby generating a compound. The compound has a high ion conductivity corresponding to a melt solution in a solid state when reaching a specific temperature.

The conductive metal ions doped on the thin film act with the internal defects of the thin film, thereby allowing a current to pass through a high-resistance amorphous chalcogenide thin film. A characteristic, in which the conductive metal ions allow a current to flow and prevent the current from flowing, is similar to a characteristic of an electrolyte, and thus, each of the conductive metal ions is called a solid electrolyte.

To briefly describe an operation mechanism of the PMC device, positive (+) Cu ions are moved to a cathode by an applied voltage, and thus, Cu⁺ ions start to be accumulated from the cathode, and are continuously accumulated upward, thereby forming a fine conduction pathway that connects a lower electrode and an upper electrode.

A rapid reduction in a resistance due to the formation of the conduction pathway maintains a turn-on state of a memory, and when the applied voltage is reversely biased, the Cu⁺ ions are separated from the conduction pathway and are changed to high-resistance resistors that prevent a current from flowing, thereby maintaining a turn-off state.

FIG. 2 is a view illustrating a cross-sectional surface of a memory 100 according to an embodiment of the present invention. As illustrated in FIG. 2, the memory 100 according to an embodiment of the present invention includes a first electrode 11, a first heat diffusion preventing layer 12, an ion conducting layer 13, a second electrode 15, and a second heat diffusion preventing layer 16.

As illustrated in FIG. 2, the first electrode 11 is disposed on a substrate 10. The substrate 10 may be a silicon substrate or a silicon-on insulator (SOI) substrate.

The first electrode 11 may be a platinum (Pt) layer, a Ru layer, an iridium (Ir) layer, or an aluminum (Al) layer. The second electrode 15 facing the first electrode 11 may be disposed on the first electrode 11. On the other hand, the first electrode 11 may be disposed on the second electrode 15. The second electrode 15 may be a Pt layer, a tungsten (W) layer, or a molybdenum (Mo) layer.

The ion conducting layer 13 may be disposed between the first electrode 11 and the second electrode 15. The ion conducting layer 14 may be formed of at least one of metal oxide, Pr_{0.7}Ca_{0.3}MnO₃ (PCMO), chalcogenide, perovskite, and a metal-doped solid electrolyte.

For example, the ion conducting layer 13 may be a perovskite layer. In detail, the perovskite layer may include SrTiO₃—X, Nb-doped SrTiO₃—X(Nb:STO), Cr-doped SrTiO₃—X(Cr:STO), BaTiO₃—X, LaMnO₃—X, SrMnO₃—X, PrTiO₃—X, PbZrO₃—X, Pr₃—YCaYMnO₃—X(PCMO), or La₃—YCaYMnO₃—X(LCMO). In more detail, the ion conducting layer 13 is an oxide layer having a P-type semiconductor characteristic, and may include Pr₃—YCaYMnO₃—X(PCMO) or La₃—YCaYMnO₃—X(LCMO).

The oxide layer 13 may be a layer in which an oxygen ratio satisfies a stoichiometry ratio or is less than a value that satisfies the stoichiometry ratio. In other words, the ion conducting layer 13 may be a non-stoichiometry layer having an oxygen vacancy. For example, in the perovskite layer, X may have a value of 023 X≦1, and Y may have a value of 0.1≦Y≦1.5.

The ion conducting layer 13 may be a single crystalline layer, an epitaxy layer, a multi-crystalline layer, or an amorphous layer. A yield rate of devices is good when the ion conducting layer 13 is the multi-crystalline layer or the amorphous layer in addition to the single crystalline layer or the epitaxy layer. However, the ion conducting layer 13 having a large area is more uniform when the ion conducting layer 13 is the multi-crystalline layer or the amorphous layer than when the ion conducting layer 13 is the single crystalline layer or the epitaxy layer. Therefore, the ion conducting layer 13 may be the multi-crystalline layer or the amorphous layer.

The ion conducting layer 13 may have a thickness of 5 nm to 20 nm For example, the ion conducting layer 13 may have a thickness of about 50 nm

Moreover, the ion conducting layer 13 may be formed by a physical vapor deposition (PVD) process, such as a sputtering process, a pulsed layer deposition (PLD) process, a thermal evaporation process, or an electron-beam evaporation process, a molecular beam epitaxy (MBE) process, or a chemical vapor deposition (CVD) process.

The first heat diffusion preventing layer 12 is disposed on a junction facing a junction between the first electrode 11 and the ion conducting layer 13. Also, the second heat diffusion preventing layer 16 is disposed on a junction facing a junction between the second electrode 15 and the ion conducting layer 13.

The first and second heat diffusion preventing layers 12 and 16 are respectively disposed on the first and second electrodes 11 and 15, and effectively prevent heat from being generated by Joule heating in a switching operation of a device. Therefore, the ion conducting layer 13 quickly moves metal ions under a high temperature. Also, heat is hardly generated in a low voltage operation, and thus, movement of metal ions is restricted.

That is, by effectively preventing heat from being generated in a switching operation, a temperature of a switching region of a device increases, and thus, an operation speed of the device becomes faster. Accordingly, heat is hardly generated in the low voltage operation, and thus, a data retention can be identically maintained.

At least one of the first and second heat diffusion preventing layers 12 and 16 may include Ge₂Sb₂Te₅ (hereinafter referred to as GST).

As shown in the following Table 1, GST has a good electrical conductivity in comparison with other materials, but a heat conductivity is relatively low, thereby effectively preventing heat from being diffused.

TABLE 1

| | c (J/m³ · K) | K (W/m · K) | ρ(Ω · cm) | S (μV/K) |
|---|---|---|---|---|
| W | 5.44 × 10⁵ | 174 | 52.8 × 10⁻⁶ | ~7.5 |
| c-PCMO | — | 0.1~2.3 | — | — |
| a-GST | 1.25 × 10⁶ | ~0.19 | ~10³ | ≧100 |
| c-GST | 1.25 × 10⁶ | ~0.57 (fcc) | ~0.002 (fcc) | ~30 |
| (RT) | | | | |
| c-GST | — | ~1.58 (hcp) | ~1.2 × 10⁻³ (hcp) | ≧60 |
| (300° C.) | | | | |

FIG. 3 is a view illustrating a cross-sectional surface of a memory 100 according to another embodiment of the present invention. As illustrated in FIG. 3, the memory 100 according to another embodiment of the present invention may further include at least one or more insulation layers 17 that are disposed on the first or second electrode 11 or 12 contacting the ion conducting layer 13, and prevent ions from being conducted.

Each of the insulation layers 17 may be a reactive metal layer. The reactive metal layer may include Mo, tantalum (Ta), titanium (Ti), or silicon (Si) that is metal having a standard free energy change amount of −100 kJ to −1100 kJ in an oxide forming reaction.

Reactive metal oxide of the reactive metal layer may be MoOₓ, TaOₓ, TiOₓ, or AlOₓ. Here, X is an integer of 1 to 3. The reactive metal oxide has an N-type semiconductor characteristic, but may be regarded as an insulation layer because having a high resistance.

The reactive metal layer may be formed in a multi-layer thin film structure having different degrees of ion diffusion. For example, the reactive metal layer may be a layer in which a first insulation layer including Ti oxide and a second insulation layer including Si oxide are formed in a layered structure.

The insulation layers 17 are added for controlling a mobility of ions so as to improve a data retention characteristic of a device. Therefore, switching may be performed when a temperature of the device has a certain level or more due to a high voltage and heating, and when a low voltage is applied, the device can maintain a data retention in a read mode.

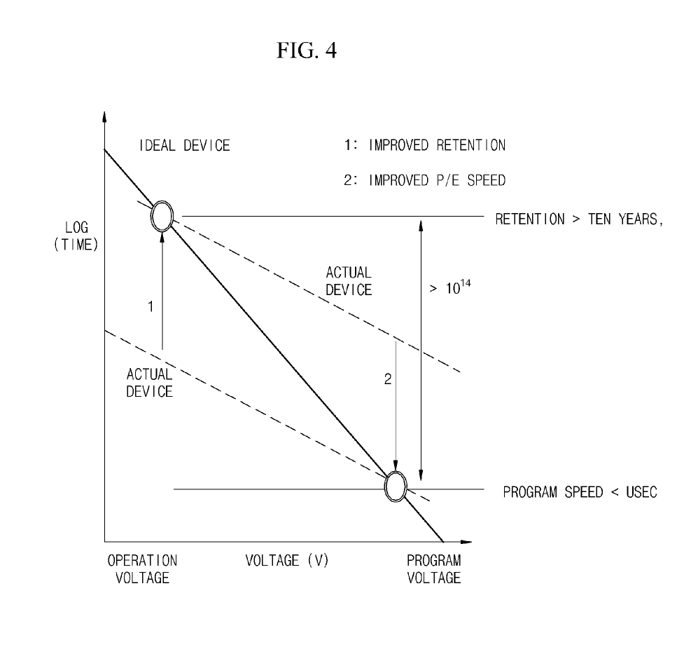

FIG. 4 is a diagram for describing an improved effect of the memory according to an embodiment of the present invention.

Referring to FIG. 4, in the memory according to an embodiment of the present invention, it can be seen that a program speed and a data retention characteristic are improved. In actual devices, the program speed (a switching operation speed) and the data retention (a durability of a memory) characteristic have a mutual tradeoff relationship, namely, have a relationship in which a durability of a memory is reduced when the switching operation speed characteristic is improved, and when the durability of the memory is improved, the switching operation speed is reduced.

According to the embodiments of the present invention, in the first and second heat diffusion preventing layers, the switching operation speed can be improved (see 2 of FIG. 4) by increasing a temperature of the switching region. In the insulation layer, a durability of a device can be improved (see 1 of FIG. 4) by adjusting a degree of ion diffusion in the ion conducting layer.

As described above, according to the present invention, since a temperature of the switching region of a device increases by adding the heat diffusion preventing layer, an operation speed increases by ten or more times, and a data retention of the device can be identically maintained. Accordingly, a voltage-time dilemma can be solved without an increase in an area of the device, thereby improving a degree of integration.

Moreover, since a high temperature is maintained in switching, a solid electrolyte in which ion conduction are relatively difficult compared to the existing device can be used, and thus, the same switching speed can be maintained, thereby considerably improving a data retention characteristic.

Moreover, at least one or more insulation layers for obstructing ion conduction are inserted into the ion conducting layer, thereby securing a stable data retention characteristic of a device. That is, by using the multi-layer thin film structure having different degrees of ion diffusion, a speed can be secured under a high voltage, and moreover, a data retention characteristic can be secured under a low voltage.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A resistive random access memory (ReRAM) comprising:
a first electrode;
a second electrode;
an ion conducting layer disposed between the first and second electrodes;
a first heat diffusion preventing layer formed on the first electrode; and
a second heat diffusion preventing layer formed on the second electrode.

2. The ReRAM of claim 1, wherein at least one of the first and second heat diffusion preventing layers comprises Ge₂Sb₂Te₅.

3. The ReRAM of claim 1, further comprising at least one or more insulation layers formed on the first or second electrode contacting the ion conducting layer, and configured to prevent ions from being conducted.

4. The ReRAM of claim 3, wherein the at least one or more insulation layers comprise Ti oxide or Si oxide.

5. The ReRAM of claim 3, wherein in the at least one or more insulation layers, a first insulation layer including Ti oxide and a second insulation layer including Si oxide are formed in a layered structure.

6. The ReRAM of claim 3, wherein the at least one or more insulation layers are formed in a multi-layer thin film structure having different degrees of ion diffusion.

7. The ReRAM of claim 1, wherein the ion conducting layer is formed of at least one of metal oxide, Pr_{0.7}Ca_{0.3}MnO₃ (PCMO), chalcogenide, perovskite, and a metal-doped solid electrolyte.
